(19) United States
(12) Patent Application Publication
(10) Pub. No.: US 2024/0234575 A9
(43) Pub. Date: Jul. 11, 2024

(54) SEMICONDUCTOR DEVICE AND METHOD OF MANUFACTURING THE SAME

(71) Applicant: Mitsubishi Electric Corporation, Tokyo (JP)

(72) Inventors: Yuki TAKIGUCHI, Tokyo (JP); Eiji YAGYU, Tokyo (JP); Kunihiko NISHIMURA, Tokyo (JP); Hisashi SAITO, Tokyo (JP); Takahiro YAMADA, Tokyo (JP); Daisuke TSUNAMI, Tokyo (JP); Marika NAKAMURA, Tokyo (JP); Masanao ITO, Tokyo (JP)

(73) Assignee: Mitsubishi Electric Corporation, Tokyo (JP)

(21) Appl. No.: 18/279,220

(22) PCT Filed: Mar. 23, 2021
(86) PCT No.: PCT/JP2021/012040

§ 371 Date: Aug. 29, 2023

(51) Int. Cl. H01L 29/78; H01L 29/417; H01L 29/423; H01L 29/66

(52) U.S. Cl. CPC H01L 29/7853; H01L 29/41791; H01L 29/4238; H01L 29/66795

(57) ABSTRACT

A semiconductor device includes a substrate, a semiconductor layer, an element region, and fin transistors. The substrate includes a principal surface. The semiconductor layer is formed as a surface layer or on the principal surface of the substrate, the surface layer being the principal surface of the substrate. The semiconductor layer has a crystal structure in which an angle between two of crystal orientations with equivalent relationships on a crystal plane having a correspondence with the principal surface of the substrate is 60 degrees or 120 degrees. The element region includes unit element regions formed on the principal surface of the substrate. The fin transistors are formed in the semiconductor layer, in the respective unit element regions. The fin transistors radially extend from a center toward an outer periphery of the element region. Adjacent two of the fin transistors have a spacing with a 60° angle or a 120° angle.

### TECHNICAL FIELD

The present disclosure relates to a semiconductor device and a method of manufacturing the same.

### BACKGROUND ART

Downsizing gate electrodes and shortening channel lengths are effective at increasing the output power and operation frequency of the transistors. However, shortening the channel lengths worsens the controllability of a drain current using a gate voltage. In other words, short-channel effects become apparent. Fin transistors are known as having structures for reducing these short-channel effects (see, for example, Patent Document 1 or 2).

### PRIOR ART DOCUMENT

### Patent Document

Patent Document 1: Japanese Patent Application Laid-Open No. 2008-235465
Patent Document 2: Japanese Patent Application Laid-Open No. 2009-130036

### Problem to be Solved by the Invention

When extension directions of multiple fin transistors vary with respect to crystal orientations of a semiconductor material of fins, variations in the properties of such fin transistors increase.

The present disclosure has an object of providing a semiconductor device including fin transistors with reduced variations in the properties to solve the problem.

### Means to Solve the Problem

The semiconductor device according to the present disclosure includes a substrate, a semiconductor layer, an element region, and multiple fin transistors. The substrate includes a principal surface. The semiconductor layer is formed as a surface layer or formed on the principal surface of the substrate, the surface layer being the principal surface of the substrate. The semiconductor layer has a crystal structure in which an angle between two of a plurality of crystal orientations with equivalent relationships on a crystal plane having a correspondence with the principal surface of the substrate is 60 degrees. The element region includes a plurality of unit element regions formed on the principal surface of the substrate. The multiple fin transistors are formed in the semiconductor layer, in the respective unit element regions. The multiple fin transistors radially extend from a center toward an outer periphery of the element region. Adjacent two of the multiple fin transistors have a spacing with a 60° angle or a 120° angle.

### Effects of the Invention

In the semiconductor device according to the present disclosure, variations in the properties of fin transistors are reduced.

The object, features, aspects, and advantages of the present disclosure will become more apparent from the following detailed description and the accompanying drawings.

### BRIEF DESCRIPTION OF DRAWINGS

FIG. 1 is a perspective view illustrating a structure of a semiconductor device according to Embodiment 1.

FIG. 2 is a top view illustrating the structure of the semiconductor device according to Embodiment 1.

FIG. 3 illustrates a structure of a fin transistor according to Embodiment 1.

FIG. 4 illustrates a structure of fin transistors according to Embodiment 1.

FIG. 5 is a flowchart illustrating a method of manufacturing the semiconductor device according to Embodiment 1.

FIG. 6 illustrates example steps for manufacturing the semiconductor device.

FIG. 7 illustrates example steps for manufacturing the semiconductor device.

FIG. 8 is a top view illustrating a structure of a semiconductor device according to Modification 1 of Embodiment 1.

FIG. 9 is a perspective view illustrating a structure of a semiconductor device according to Embodiment 2.

FIG. 10 illustrates a structure of a fin transistor according to Embodiment 2.

FIG. 11 is a perspective view illustrating a structure of a semiconductor device according to Embodiment 3.

FIG. 12 illustrates a structure of a fin transistor according to Embodiment 3.

FIG. 13 is a perspective view illustrating a structure of a semiconductor device according to Embodiment 4.

FIG. 14 illustrates a structure of fin transistors according to Embodiment 4.

FIG. 15 is a perspective view illustrating a structure of a semiconductor device according to Embodiment 5.

FIG. 16 is a top view illustrating the structure of the semiconductor device according to Embodiment 5.

FIG. 17 is a perspective view illustrating a structure of a semiconductor device according to Embodiment 6.

FIG. 18 illustrates a structure of a fin transistor according to Embodiment 6.

### DESCRIPTION OF EMBODIMENTS

Hereinafter, Embodiments will be described with reference to the accompanying drawings. The drawings are schematically illustrated. Thus, horizontal and vertical dimensions of constituent elements in the drawings do not accurately represent actual dimensions, and dimension ratios of these are not accurate. The words representing positions and directions including “up”, “down”, and “side” are used for convenience to describe Embodiments, and do not always represent actual directions in which semiconductor devices are used or mounted.

### Embodiment 1

### [Overall Structure of Semiconductor Device]

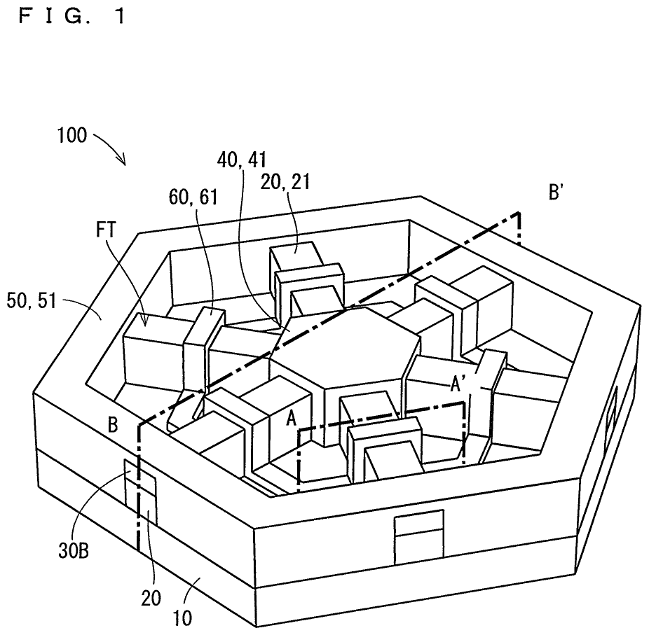

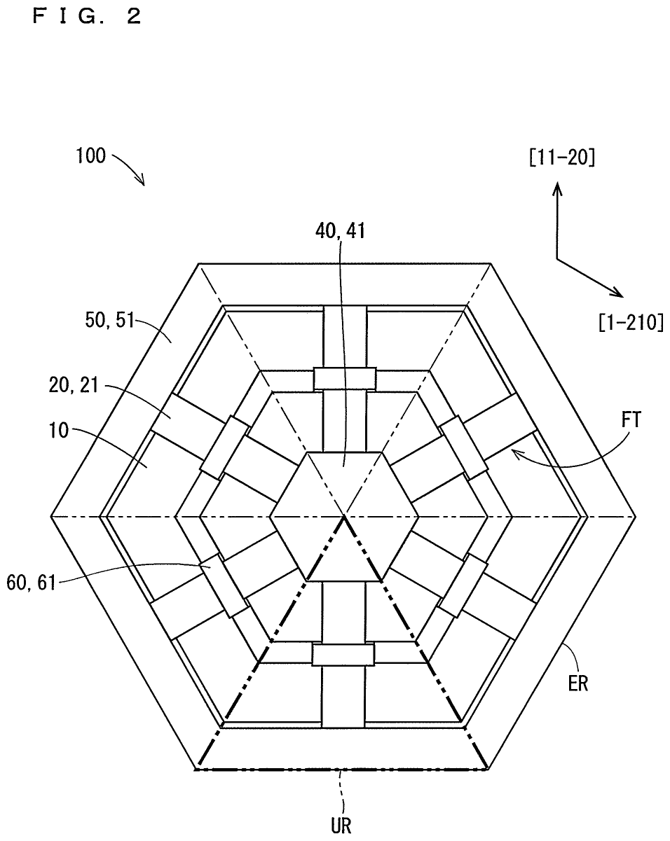

FIG. 1 is a perspective view illustrating a structure of a semiconductor device 100 according to Embodiment 1. FIG. 2 is a top view illustrating the structure of the semiconductor device 100.

The semiconductor device 100 includes a substrate 10, a semiconductor layer 20, an element region ER, and multiple fin transistors FT. The semiconductor device 100 includes six fin transistors FT in Embodiment 1.

The substrate 10 is made of a semiconductor material or an insulating material. Examples of the semiconductor material include Si, SiC, GaAs, GaN, AlN, InP, and Ga₂O₃. Examples of the insulating material include Al₂O₃, MgO, and diamond. Diamond may be defined as a semiconductor material. The substrate 10 preferably has a crystal structure in which an angle between two of a plurality of crystal orientations with equivalent relationships on its principal surface is 60 degrees. The principal surface is, for example, an upper surface of the substrate 10.

The semiconductor layer 20 is formed on the principal surface of the substrate 10. Alternatively, the semiconductor layer 20 may be formed as a surface layer of the substrate 10 which is the principal surface of the substrate 10. The semiconductor layer 20 has a crystal structure in which an angle between two of a plurality of crystal orientations with equivalent relationships on a crystal plane having a correspondence with the principal surface of the substrate 10 is 60 degrees. For example, when the semiconductor layer 20 has a crystal structure rotationally symmetric at 60 degrees, the angle between two crystal orientations with equivalent relationships is 60 degrees. Hereinafter, the crystal orientations may be referred to as crystal axes. The crystal plane having a correspondence with the principal surface of the substrate 10 is, for example, a plane parallel to the principal surface of the substrate 10. The crystal plane having a correspondence with the principal surface of the substrate 10 will be referred to as a principal crystal plane. The semiconductor layer 20 includes a plurality of crystal axes with equivalent relationships on the principal crystal plane. The semiconductor layer 20 is made of, for example, a semiconductor material with a hexagonal crystal structure, such as GaN, 4H—SiC, 6H—SiC, α-Ga₂O₃, or ZnO. When the semiconductor layer 20 has a hexagonal crystal structure, its principal crystal plane is a (0001) plane. The crystal axes with equivalent relationships are six axes extending in a [11-20] direction, a [−1-120] direction, a [1-210] direction, a [−12-10] direction, a [−2110] direction, and a [2-1-10] direction. These equivalent crystal axes will be hereinafter collectively referred to as axes in <11-20> directions.

The element region ER includes six unit element regions UR formed on the principal surface of the substrate 10. In Embodiment 1, the outer shape of the element region ER is a hexagon, and the outer shape of the unit element region UR is an equilateral triangle. The element region ER is formed by arranging the six unit element regions UR in a circumferential direction. The element region ER in Embodiment 1 has a planar arrangement with 6-fold symmetry.

The fin transistors FT are formed in the semiconductor layer 20, in the respective unit element regions UR. The six fin transistors FT radially extend from the center toward the outer periphery of the element region ER. The adjacent two fin transistors FT have a spacing with a 60° angle. The extension direction of each of the fin transistors FT corresponds to one of the six equivalent crystal orientations on the principal crystal plane of the semiconductor layer 20. The six fin transistors FT in Embodiment 1 radially extend in the six crystal orientations of the semiconductor layer 20, that is, in the <11-20> directions.

[Structure of Fin Transistor]

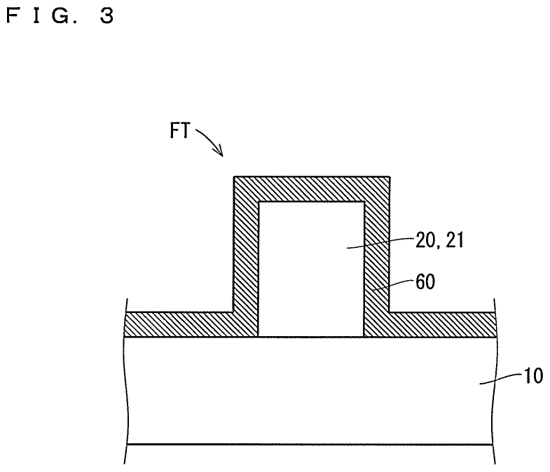

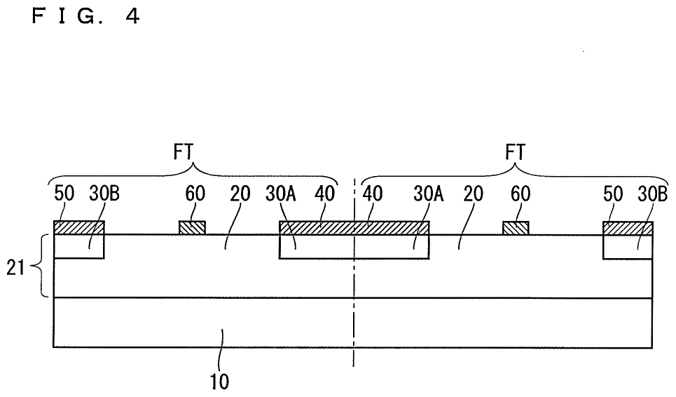

FIGS. 3 and 4 illustrate a structure of the fin transistor(s) FT according to Embodiment 1. FIG. 3 is a cross-sectional view taken along A-A′ of FIG. 1. FIG. 4 is a cross-sectional view taken along B-B′ of FIG. 1.

Each of the fin transistors FT includes a fin 21, a first contact region 30A, a second contact region 30B, a drain electrode 40, a source electrode 50, and a gate electrode 60. The fin 21 is formed in the semiconductor layer 20 of the first conductivity type. The first contact region 30A and the second contact region 30B that are formed in the fin 21 have the second conductivity type. When the first conductivity type is n-type, the second conductivity type is p-type. When the first conductivity type is p-type, the second conductivity type is n-type.

The fin 21 is formed in the semiconductor layer 20, and extends from the center toward the outer periphery of the element region ER. The fin 21 has a protruding shape in a cross section vertical to the extension direction. The fins 21 in Embodiment 1 extend in the <11-20> directions with equivalent relationships, on the principal crystal plane of the semiconductor layer 20. The side surfaces of the fin 21 are formed almost vertical to the principal surface of the substrate 10. Thus, the side surfaces of the six fins 21 are crystal planes with equivalent relationships. The side surfaces of each of the fins 21 in Embodiment 1 are {1-100} planes. The {1-100} planes are a generic name for planes equivalent to (1-100) planes. Specifically, the {1-100} planes include six planes of a (1-100) plane, a (−1100) plane, a (10-10) plane, a (−1010) plane, a (01-10) plane, and a (0-110) plane.

The six fins 21 are mutually connected at the center of the element region ER. Hereinafter, an end of the fin 21 at the center of the element region ER will be referred to as a first end. An end of the fin 21 opposite to the first end will be referred to as a second end.

The first contact region 30A is formed in a surface layer of the fin 21, at the first end located at the center of the element region ER. The first contact region 30A in each of the unit element regions UR is connected to the first contact regions 30A in the other unit element regions UR, at the center of the element region ER. In other words, the first contact regions 30A have commonality.

The second contact region 30B is formed in the surface layer of the fin 21, at the second end opposite to the first end.

The drain electrode 40 is formed on the first contact region 30A. The drain electrode 40 is in ohmic contact with the first contact region 30A. The drain electrode 40 in each of the unit element regions UR is connected to the drain electrodes 40 in the other unit element regions UR, at the center of the element region ER. In other words, the semiconductor device 100 includes a common drain electrode 41 at the center of the element region ER. The drain electrodes 40 of the six fin transistors FT make up the common drain electrode 41, and have commonality. The drain electrodes 40 are made of, for example, a metal, an alloy, a chemical compound including a metal and a semiconductor, or a semiconductor material doped with impurities. Examples of the metals include Al, Au, Ti, W, Ta, Ni, Ga, Co, and Pd.

The source electrode 50 is formed on the second contact region 30B. The source electrode 50 is in ohmic contact with the second contact region 30B. The source electrode 50 in each of the unit element regions UR is connected to the source electrodes 50 in the adjacent unit element regions UR, at the outer periphery of the element region ER. In other words, the semiconductor device 100 includes a ring-shaped source electrode 51 at the outer periphery of the element region ER. The source electrodes 50 of the six fin transistors FT make up the ring-shaped source electrode 51, and have commonality. The source electrodes 50 are made of, for example, a metal, an alloy, a chemical compound including a metal and a semiconductor, or a semiconductor material doped with impurities. Examples of the metals include Al, Au, Ti, W, Ta, Ni, Ga, Co, and Pd.

The gate electrode 60 is formed across the fin 21. The gate electrodes 60 are separated from the drain electrodes 40 and the source electrodes 50. The gate electrode 60 covers a part of the side surfaces and a part of the upper surface of the fin 21. The gate electrode 60 in Embodiment 1 is in contact with both of the side surfaces and the upper surface of the fin 21. The gate electrode 60 forms a Schottky contact with the fin 21. A channel is controlled from both of the side surfaces and the upper surface of the fin 21.

The gate electrode 60 in each of the unit element regions UR is connected to the gate electrodes 60 in the adjacent unit element regions UR. In other words, the semiconductor device 100 includes a ring-shaped gate electrode 61 that is formed in a ring. The gate electrodes 60 of the six fin transistors FT make up the ring-shaped gate electrode 61, and have commonality. The gate electrodes 60 are made of, for example, a metal, an alloy, a chemical compound including a metal and a semiconductor, or a semiconductor material doped with impurities. Examples of the metals include Al, Au, Ti, W, Ta, Ni, Ga, Co, and Pd.

[Method of Manufacturing the Semiconductor Device 100]

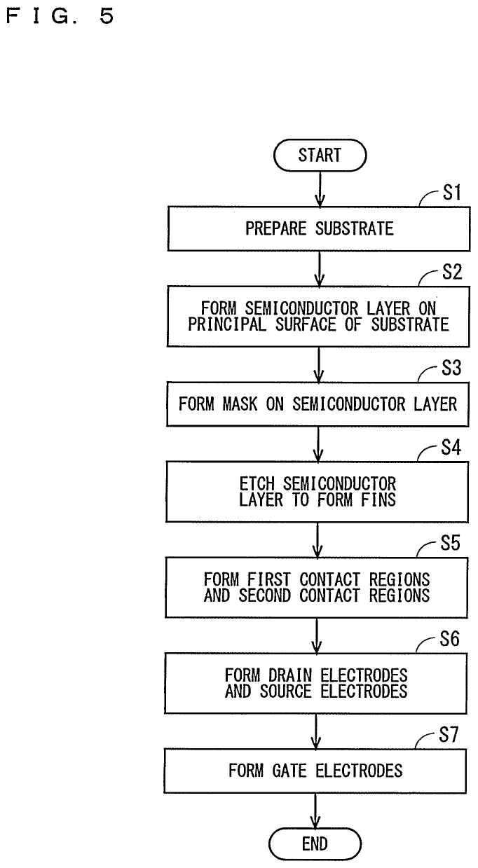

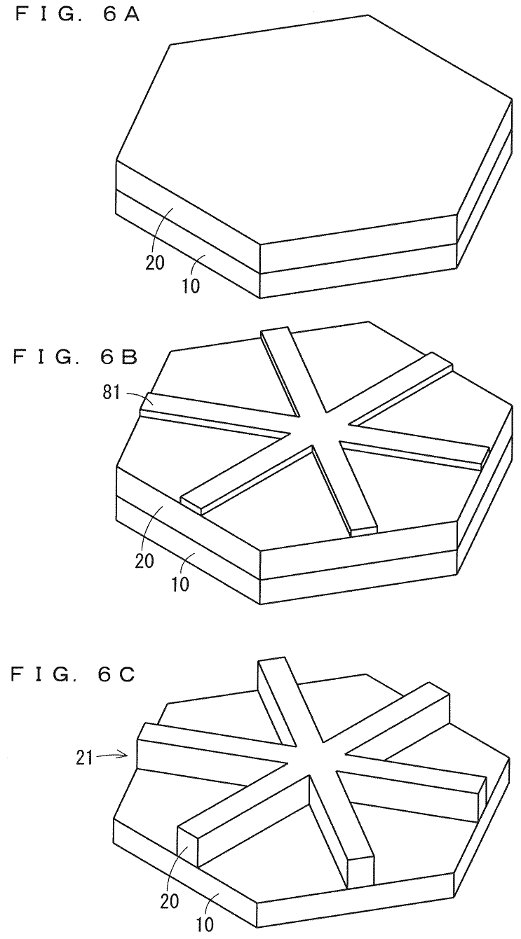

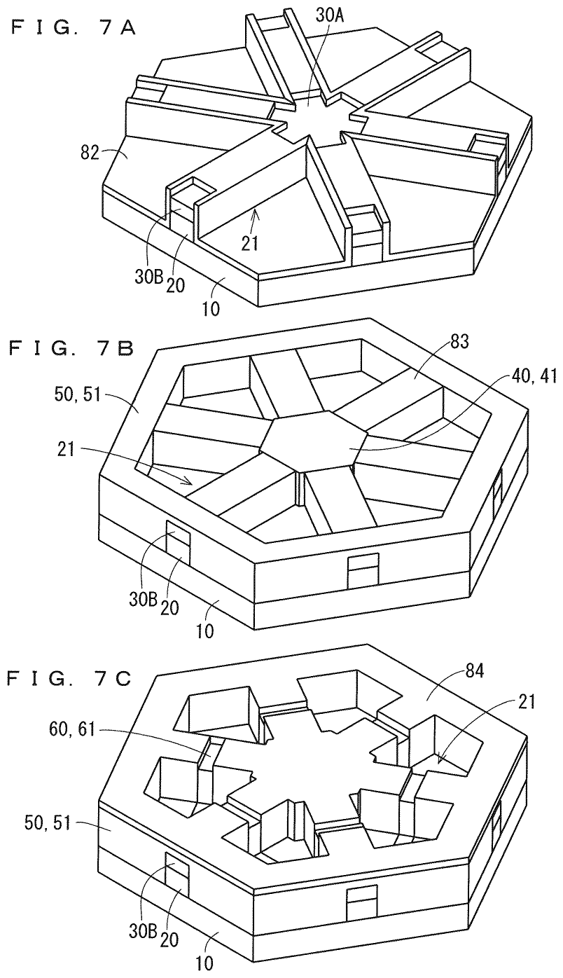

FIG. 5 is a flowchart illustrating a method of manufacturing the semiconductor device 100 according to Embodiment 1. FIG. 6 (a) to FIG. 6 (c) and FIG. 7 (a) to FIG. 7 (c) illustrate example steps for manufacturing the semiconductor device 100.

In Step S1, the substrate 10 is prepared. For example, the substrate 10 is a GaN substrate, and its principal surface is a (0001) plane. An angle between two crystal orientations with equivalent relationships on the (0001) plane of the GaN substrate is 60 degrees.

In Step S2, the semiconductor layer 20 is formed on the principal surface of the substrate 10. FIG. 6 (a) is a perspective view illustrating a step for forming the semiconductor layer 20. The semiconductor layer 20 is formed by, for example, the metal organic chemical vapor deposition (MOCVD). The semiconductor layer 20 is, for example, a GaN layer of the first conductivity type. The GaN layer is epitaxially grown on the principal surface of the GaN substrate. Thus, a crystal structure of the GaN substrate is reflected onto a crystal structure of the GaN layer. Thus, an angle between two crystal orientations with equivalent relationships on the principal crystal plane, that is, the (0001) plane of the GaN layer is 60 degrees. In other words, six crystal orientations with equivalent relationships exist on the (0001) plane of the GaN layer.

In Steps S3 to S7, the element region ER including the plurality of unit element regions UR is formed on the substrate 10. As illustrated in FIG. 2, the unit element regions UR each with an equilateral triangle, and the hexagonal element region ER including the unit element regions UR are formed in Embodiment 1. In other words, the element region ER with the planar arrangement of 6-fold symmetry is formed. The fin transistors FT are formed in the semiconductor layer 20, in the respective unit element regions UR. The six fin transistors FT radially extend in the six crystal orientations of the semiconductor layer 20. The adjacent two fin transistors FT have a spacing with a 60° angle. The details of the method of forming the element region ER will be hereinafter described.

In Step S3, a mask is formed on the semiconductor layer 20. FIG. 6 (b) is a perspective view illustrating a step for forming a mask 81. The mask 81 is formed in the following steps. First, a mask material is applied onto the semiconductor layer 20. The mask material is, for example, a photosensitive resin, and its application method is spin coating. The mask 81 is formed on regions for forming the fins 21 by a lithographic technique such as optical exposure. In this case, the mask 81 is formed so that extension directions of the regions for forming the six fins 21 match the six crystal orientations on the principal crystal plane of the semiconductor layer 20.

In Step S4, the semiconductor layer 20 is etched to form the fins 21. FIG. 6 (c) is a perspective view illustrating a step for forming the six fins 21. The semiconductor layer 20 is etched through the mask 81. The fins 21 are formed by dry etching, for example, reactive ion etching (RIE). For example, the GaN layer is etched by plasma containing chlorine gas. The six fins 21 are formed by the etching.

In Step S5, the first contact regions 30A and the second contact regions 30B are formed. FIG. 7 (a) is a perspective view illustrating a step for forming the first contact regions 30A and the second contact regions 30B. First, a mask material is applied onto the substrate 10 and the fins 21 to form a mask 82. The application method is spin coating. Openings are formed to correspond to regions for forming the first contact regions 30A and the second contact regions 30B by a lithographic technique. Dopants are selectively ion-implanted into the semiconductor layer 20 at both ends of the fins 21 through the openings of the mask 82. This forms the first contact regions 30A of the second conductivity type in the surface layer and at the first ends of the fins 21. This also forms the second contact regions 30B in the surface layer and at the second ends of the fins 21.

In Step S6, the drain electrodes 40 and the source electrodes 50 are formed. FIG. 7 (b) is a perspective view illustrating a step for forming the drain electrodes 40 and the source electrodes 50. A mask 83 with openings corresponding to regions for forming the drain electrodes 40 and the source electrodes 50 is formed on the substrate 10. Here, the openings are formed so that the region for forming the drain electrode 40 in each of the unit element regions UR is connected to the regions for forming the drain electrodes 40 in the other unit element regions UR, at the center of the element region ER. Furthermore, the openings are formed so that the region for forming the source electrode 50 in each of the unit element regions UR is connected to the regions for forming the source electrodes 50 in the adjacent unit element regions UR, at the outer periphery of the element region ER. For example, a metal film is formed on the first contact regions 30A and the second contact regions 30B through the openings of the mask 83. The metal film is formed by, for example, vapor deposition. This forms the drain electrodes 40 and the source electrodes 50. At the same time, connecting the drain electrodes 40 in the six unit element regions UR forms the common drain electrode 41. Similarly, connecting the source electrodes 50 in the six unit element regions UR forms the ring-shaped source electrode 51.

In Step S7, the gate electrodes 60 are formed. FIG. 7 (c) is a perspective view illustrating a step for forming the gate electrodes 60. A mask 84 with openings corresponding to regions for forming the gate electrodes 60 is formed on the substrate 10. For example, a metal film is formed on the fins 21 between first contact regions 30A and the second contact regions 30B, through the openings of the mask 84. The metal film is formed by, for example, vapor deposition. This forms the gate electrodes 60. At the same time, connecting the gate electrodes 60 in the six unit element regions UR forms the ring-shaped gate electrode 61. The semiconductor device 100 is completed through the aforementioned steps.

To sum up, the semiconductor device 100 according to Embodiment 1 includes the substrate 10, the semiconductor layer 20, the element region ER, and the multiple fin transistors FT. The semiconductor layer 20 is formed on the principal surface of the substrate 10. The semiconductor layer 20 has a crystal structure in which an angle between two of a plurality of crystal orientations with equivalent relationships on a crystal plane having a correspondence with the principal surface of the substrate 10 is 60 degrees. The element region ER includes the plurality of unit element regions UR formed on the substrate 10. The multiple fin transistors FT are formed in the semiconductor layer 20, in the respective unit element regions UR. The multiple fin transistors FT radially extend from the center toward the outer periphery of the element region ER. The adjacent two of the multiple fin transistors FT have a spacing with a 60° angle.

In the semiconductor device 100, variations in properties of the fin transistors FT are reduced. Furthermore, the semiconductor device 100 achieves the high power density, and suppresses short channel effects.

Increasing output power of transistors for high power amplifiers or high-power switching devices per unit area is important for downsizing chip areas. The width of a fin of a fin transistor for maintaining the controllability using a gate voltage is approximately several hundred nanometers at the longest. However, the output power is proportional to the width of the fin. Thus, multiple fin transistors are necessary for increasing the output.

Arranging multiple fin transistors in parallel on one substrate can hardly increase its density, and reduces the output power per unit area. Although arranging multiple fin transistors at different angles achieves the high power density, appropriate selection of extension directions of the fin transistors and crystal orientations of a semiconductor layer is necessary.

Furthermore, transport properties of charges moving within a semiconductor material depend on an effective mass of the charges. The effective mass of the charges depends on an atomic arrangement of the semiconductor material. When the multiple fin transistors extend in different crystal orientations, transport properties of charges moving within the fins differ for each of the fins. In other words, unit elements have variations in the properties.

The fin transistor FT according to Embodiment 1 extend in crystal orientations with equivalent relationships. For example, one of the fins 21 extends in the [11-20] direction of the semiconductor layer 20. The other fins 21 extend in directions rotated in increments of 60 degrees from the [11-20] direction with respect to the drain electrodes 40. As described above, the angle between two of the plurality of crystal orientations with equivalent relationships on the principal crystal plane of the semiconductor layer 20 is 60 degrees. Thus, the six fins 21 in Embodiment 1 extend in the <11-20> directions of the semiconductor layer 20 which have equivalent relationships. The fins 21 arranged in this manner have the identical transport properties of charges. Thus, variations in the properties among the unit elements are reduced. This consequently improves the performance of the semiconductor device 100.

Furthermore, growth processes or etching processes of a semiconductor material depend on chemical and physical properties of the surface of the semiconductor material. The chemical and physical properties of the semiconductor material are changed by an atomic arrangement on the surface. The atomic arrangement on the surface differs for each crystal plane. For example, a crystal growth rate differs for each crystal plane. Furthermore, an etch rate is changed depending on a crystal plane, and differences in surface state after the etching occur depending on the crystal plane. When the multiple fin transistors FT are formed on the single substrate 10, no association between extension directions of the fins 21 and crystal planes creates fabrication variations in the widths of the fins 21 and the surface states of the fins 21.

As described above, the fin transistors FT extend in the crystal orientations with equivalent relationships. Each of the fins 21 extends in the <11-20> direction, and the side surfaces of each of the fins 21 are equivalent {1-100} planes. This reduces the fabrication variations in the fins 21, and further reduces variations in, for example, threshold voltage and output of the fin transistors FT. This consequently improves the performance of the semiconductor device 100.

If four fin transistors FT are arranged so that the fins 21 extend in directions rotated in increments of 90 degrees with respect to the drain electrodes 40, the side surfaces of the fin 21 extending in the <11-20> direction are the {1-100} planes, whereas the side surfaces of the fin 21 extending in the <1-100> direction are {11-20} planes. Different crystal planes appear on the side surfaces of the fin 21 for each of the unit element regions UR. This causes not only variations in transport properties of charges but also fabrication variations in the fins 21.

The fins 21 of the six fin transistors FT are formed in the semiconductor layer 20 with the same conductivity type. Since the drain electrodes 40, the source electrodes 50, and the gate electrodes 60 have respective commonalities, the six fin transistors FT operate in the same manner. In other words, the six fin transistors FT function as one switching element. Such a structure achieves the high power density.

### Modification 1 of Embodiment 1

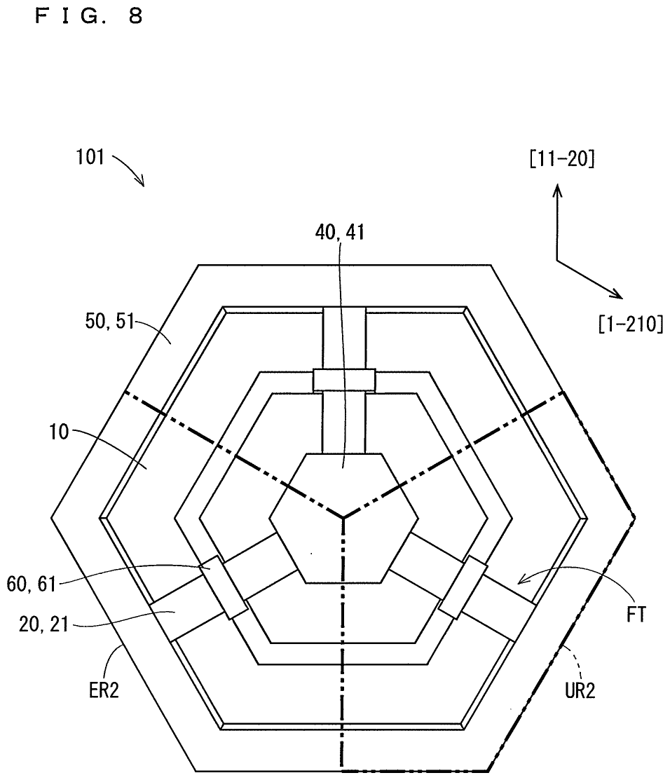

FIG. 8 is a top view illustrating a structure of a semiconductor device 101 according to Modification 1 of Embodiment 1.

An element region ER2 includes three unit element regions UR2. The element region ER2 is formed by arranging the three unit element regions UR2 in a circumferential direction. The element region ER2 has a planar arrangement with 3-fold symmetry.

Three fin transistors FT are formed in the semiconductor layer 20, in the respective three unit element regions UR2. The adjacent two of the fin transistors FT have a spacing with a 120° angle. The extension direction of each of the fin transistors FT corresponds to one of the six equivalent crystal orientations on the principal crystal plane of the semiconductor layer 20. For example, the three transistors extend in the [11-20] direction, the [1-210] direction, and the [−2110] direction.

### Modification 2 of Embodiment 1

Although the six fin transistors FT extend in the <11-20> directions in Embodiment 1, the extension directions of the fins 21 are not limited to the <11-20> directions. The six fins 21 should extend in equivalent crystal orientations. For example, one of the fins 21 may extend in a [1-100] direction of the semiconductor layer 20, and the other fins 21 may extend in directions rotated in increments of 60 degrees from the [1-100] direction with respect to the drain electrodes 40.

### Modification 3 of Embodiment 1

The semiconductor layer 20 may be made of a semiconductor material with a tetragonal crystal structure, such as Si, 3C—SiC, GaAs, or diamond. When the semiconductor layer 20 has a tetragonal crystal structure, its principal crystal plane is a (111) plane. The semiconductor layer 20 may be made of a two-dimensional layered material such as graphene or WSe₂.

### Modification 4 of Embodiment 1

A contact layer (not illustrated) excessively doped with impurities more than its periphery may be formed in a surface layer of the first contact region 30A. Such a contact layer reduces the contact resistance with the drain electrode 40. As long as the first contact region 30A is apart from the gate electrode 60, the first contact regions 30A may extend off toward the gate electrode 60 with respect to the drain electrode 40.

A contact layer (not illustrated) excessively doped with impurities more than its periphery may be formed in a surface layer of the second contact region 30B. Such a contact layer reduces the contact resistance with the source electrode 50. As long as the second contact region 30B is apart from the gate electrode 60, the second contact region 30B may extend off toward the gate electrode 60 with respect to the source electrode 50.

The drain electrodes 40 may be interchanged with the source electrodes 50 in the arrangement. In other words, the source electrodes 50 may be arranged at the center of the element region ER, whereas the drain electrodes 40 may be arranged at the outer periphery of the element region ER.

An air gap or an insulator may be disposed between the gate electrode 60 and the upper surface of the fin 21. In other words, the gate electrode 60 may be in contact with only both sides of the fin 21. Here, a channel is controlled from both of the side surfaces of the fin 21.

Although the fins 21 in Embodiment 1 are formed by etching the semiconductor layer 20, the method of forming the fins 21 is not limited to the etching. Selectively growing a semiconductor material contained in the fins 21 on the principal surface of the substrate 10 may form the fins 21 with protruding shapes.

The method of forming the semiconductor layer 20 is not limited to the epitaxial growth method. The semiconductor layer 20 may be a layer obtained by ion-implanting impurities into the surface layer of the substrate 10.

### Modification 5 of Embodiment 1

Although Embodiment 1 and Modification 1 of Embodiment 1 describe examples where the extension directions of the fin transistors FT match the equivalent crystal orientations of the semiconductor layer 20, the extension directions are not limited to the crystal orientations. As long as the semiconductor layer 20 has a crystal structure in which an angle between two crystal orientations with equivalent relationships on its principal surface is 60 degrees and the adjacent two fin transistors FT have a spacing with a 60° angle or a 120° angle, the extension directions of the fin transistors FT may be displaced from the crystal orientations. In other words, the six fin transistors FT may be arranged rotationally in increments of the same angle from the crystal orientations. Since the six fins 21 are displaced from the equivalent crystal orientations in the same manner, variations in the properties of the six fin transistors FT are reduced.

### Embodiment 2

A semiconductor device and a method of manufacturing the same according to Embodiment 2 will be described. In Embodiment 2, the same references will be applied to the constituent elements identical to those in Embodiment 1, and the detailed description thereof will be omitted.

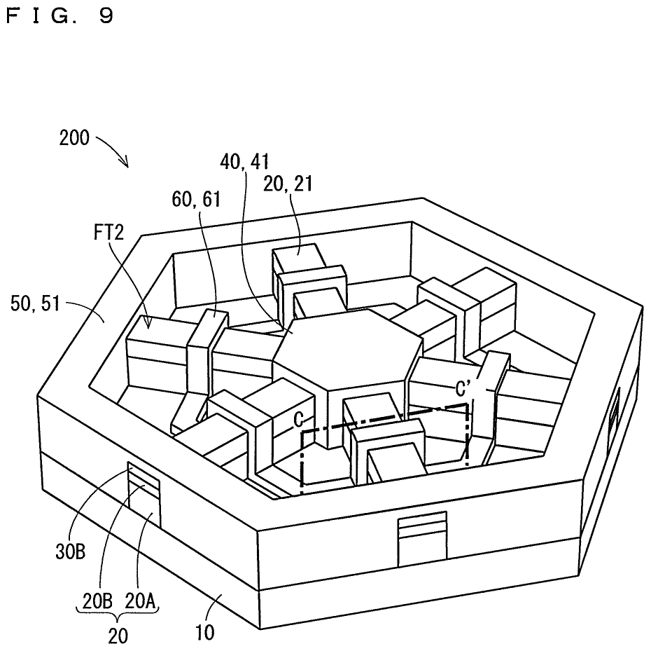

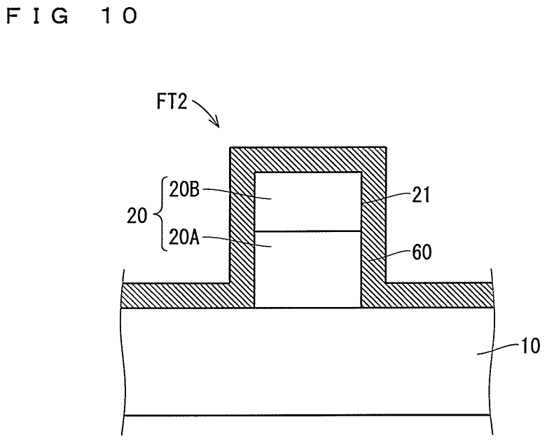

FIG. 9 is a perspective view illustrating a structure of a semiconductor device 200 according to Embodiment 2. FIG. 10 illustrates a structure of a fin transistor FT2 according to Embodiment 2. FIG. 10 is a cross-sectional view taken along C-C′ of FIG. 9.

The gate electrodes 60 include a semiconductor containing impurities. For example, the gate electrodes 60 include polysilicon containing impurities, that is, having conductivity. The gate electrode 60 covers both side surfaces and the upper surface of the fin 21.

The semiconductor layer 20 included in the fin 21 includes a lower layer 20A with a conductivity type identical to that of the gate electrodes 60, and an upper layer 20B with a conductivity type different from that of the gate electrodes 60. Both side surfaces of the lower layer 20A are in contact with the gate electrode 60. Both side surfaces and the upper surface of the upper layer 20B are in contact with the gate electrode 60.

The lower layer 20A and the gate electrode 60 are made of, for example, a material allowing formation of an Ohmic contact between the side surfaces of the lower layer 20A and the gate electrode 60. The upper layer 20B and the gate electrode 60 are made of, for example, a material allowing formation of a Schottky contact between the side surfaces and the upper surface of the upper layer 20B and the gate electrode 60.

Each of the lower layer 20A and the upper layer 20B has a crystal structure in which an angle between two crystal orientations with equivalent relationships on a crystal plane is 60 degrees. The crystal structure of each of the lower layer 20A and the upper layer 20B has six equivalent crystal orientations. The fins 21 each including the lower layer 20A and the upper layer 20B extend in the equivalent crystal orientations with respect to the drain electrodes 40.

The conductivity types of the lower layer 20A and the upper layer 20B are controlled by, for example, crystal growth processes. In other words, the lower layer 20A and the upper layer 20B are doped with impurities of different conductivity types. Alternatively, the conductivity types of the lower layer 20A and the upper layer 20B are controlled by ion implantation. In other words, after the lower layer 20A and the upper layer 20B are formed in the same manner by crystal growth, impurities of a conductivity type different from that of the lower layer 20A are ion-implanted into the upper layer 20B.

A potential of the lower layer 20A is equal to that of the gate electrode 60 in the semiconductor device 200. The lower layer 20A effectively functions in the same manner as the gate electrode 60 for the upper layer 20B. A channel of the upper layer 20B is controlled by the gate electrode 60 and the lower layer 20A. In other words, the channel is controlled from both side surfaces and upper and lower surfaces of the upper layer 20B of the fin 21. Since the gate electrode 60 is in contact with both side surfaces and the upper surface of the fin 21 in Embodiment 1, the channel is controlled from the side surfaces and the upper surface of the fin 21. Furthermore, since the gate electrode 60 is in contact with both side surfaces of the fin 21 in Modification 4 of Embodiment 1, the channel is controlled from the side surfaces of the fin 21. The channel controllability of the semiconductor device 200 is improved more than that of the semiconductor device 100. The semiconductor device 200 suppresses short channel effects.

The gate electrode 60 may be in contact with only both side surfaces of the lower layer 20A and both side surfaces of the upper layer 20B in the fin 21, and need not be in contact with the upper surface of the upper layer 20B. In this case, the channel is controlled from both side surfaces and the lower surface of the upper layer 20B of the fin 21.

As long as each of the lower layer 20A and the upper layer 20B is a semiconductor with a crystal structure in which an angle between two crystal orientations with equivalent relationships on a crystal plane is 60 degrees, the lower layer 20A and the upper layer 20B may be made of different materials.

### Embodiment 3

A semiconductor device and a method of manufacturing the same according to Embodiment 3 will be described. In Embodiment 3, the same references will be applied to the constituent elements identical to those in Embodiment 1 or 2, and the detailed description thereof will be omitted.

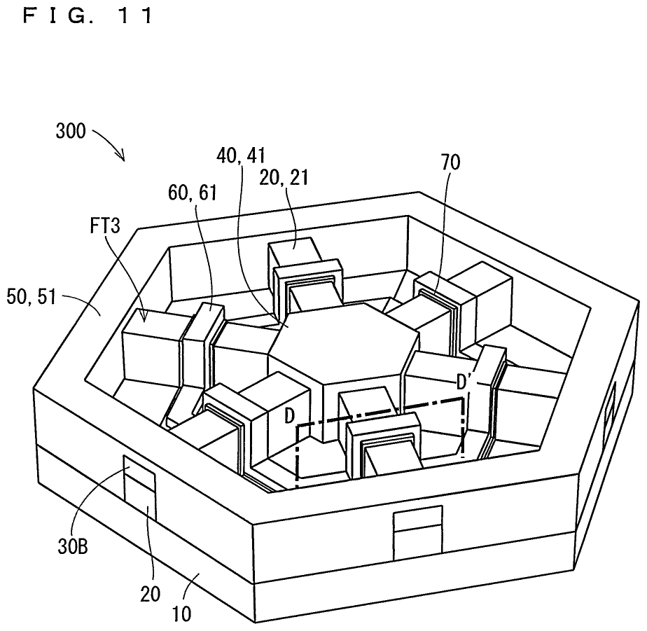

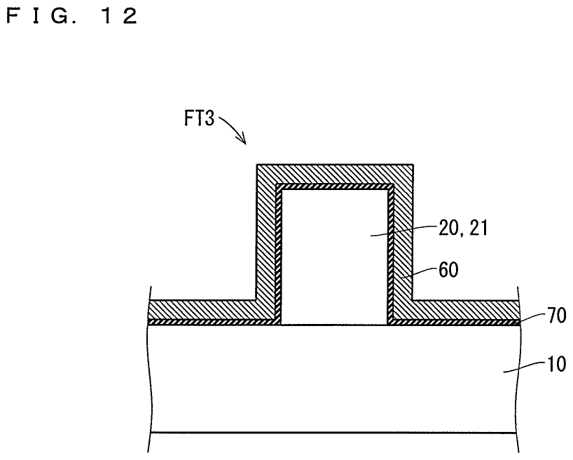

FIG. 11 is a perspective view illustrating a structure of a semiconductor device 300 according to Embodiment 3. FIG. 12 illustrates a structure of a fin transistor FT3 according to Embodiment 3. FIG. 12 is a cross-sectional view taken along D-D′ of FIG. 11.

The fin transistor FT3 includes a gate insulating film 70. The insulating film 70 is formed between the fin 21 and the gate electrode 60. The gate insulating film 70 is made of, for example, an oxide material, a nitride material, or a mixed crystal material. The oxide may be a metal oxide or an oxide of a semiconductor. Examples of the oxide material include SiO₂, Al₂O₃, HfO₂, Gd₂O₃, Ta₂O₃, and ZrO₂. The nitride may be a metal nitride or a nitride of a semiconductor. Examples of the nitride material include SiN, AlN, TiN, and MoN. The mixed crystal material is a mixed crystal of the oxide material and the nitride material.

The gate electrode 60 is in contact with both side surfaces and the upper surface of the fin 21 through the gate insulating film 70. The gate insulating film 70 reduces the leakage current between the fin 21 and the gate electrode 60. Thus, the power efficiency of the semiconductor device 300 is improved more than that of the semiconductor device 100.

The gate electrode 60 may be in contact with only both side surfaces of the fin 21, and need not be in contact with the upper surface of the fin 21.

The gate insulating film 70 may be applied to the semiconductor device 200. The semiconductor device 200 produces the same advantages as described above.

### Embodiment 4

A semiconductor device and a method of manufacturing the same according to Embodiment 4 will be described. In Embodiment 4, the same references will be applied to the constituent elements identical to those in any one of Embodiments 1 to 3, and the detailed description thereof will be omitted.

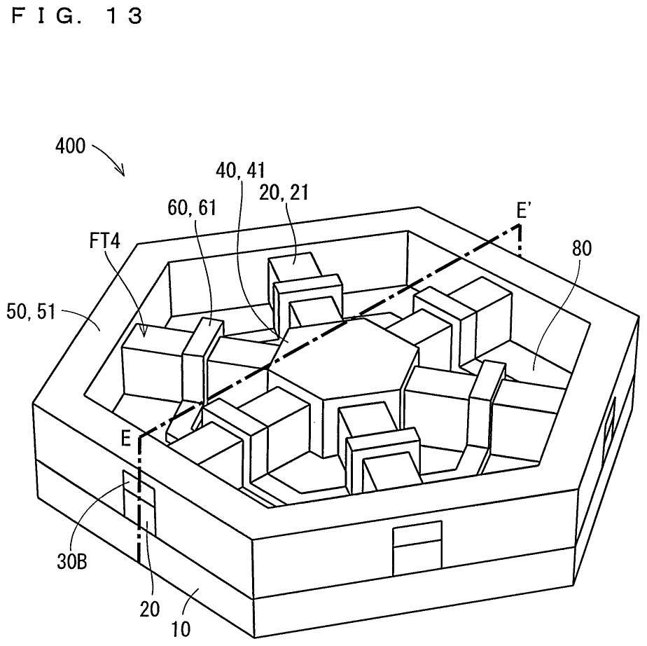

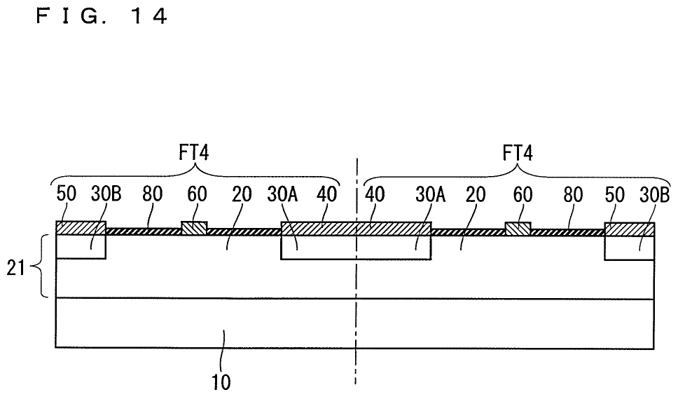

FIG. 13 is a perspective view illustrating a structure of a semiconductor device 400 according to Embodiment 4. FIG. 14 illustrates a structure of fin transistors FT4 according to Embodiment 4. FIG. 14 is a cross-sectional view taken along E-E′ of FIG. 13.

The fin transistor FT4 includes an insulating film 80. The insulating film 80 covers regions not covered with the gate electrode 60 on both side surfaces and the upper surface of the fin 21. The insulating film 80 may cover not only the fin 21 but also the upper surface of the substrate 10. The insulating film 80 is made of an oxide material, a nitride material, or a mixed crystal material. The oxide may be a metal oxide or an oxide of a semiconductor. Examples of the oxide material include SiO₂, Al₂O₃, HfO₂, Gd₂O₃, Ta₂O₃, and ZrO₂. The nitride may be a metal nitride or a nitride of a semiconductor. Examples of the nitride material include SiN, AlN, TiN, and MoN. The mixed crystal material is a mixed crystal of the oxide material and the nitride material.

The insulating film 80 is formed, for example, in the following steps. A film of an insulating material is formed on the surface of the semiconductor device 100 in Embodiment 1 by chemical vapor deposition (CVD) such as atomic layer deposition (ALD). The insulating material is selectively removed by forming a mask pattern and etching. This forms the insulating film 80.

Covering the surface of the semiconductor layer 20 with the insulating film 80 reduces a defect density caused by many dangling bonds on the surface of the semiconductor layer 20. In other words, the insulating film 80 prevents defects caused by dangling bonds from trapping charges in a channel and reducing a channel charge density. The output and the power efficiency of the semiconductor device 400 are improved more than those of the semiconductor device 100.

The insulating film 80 may be applied to the semiconductor device 200 or 300. The semiconductor device produces the same advantages as described above.

### Embodiment 5

A semiconductor device and a method of manufacturing the same according to Embodiment 5 will be described. In Embodiment 5, the same references will be applied to the constituent elements identical to those in any one of Embodiments 1 to 4, and the detailed description thereof will be omitted.

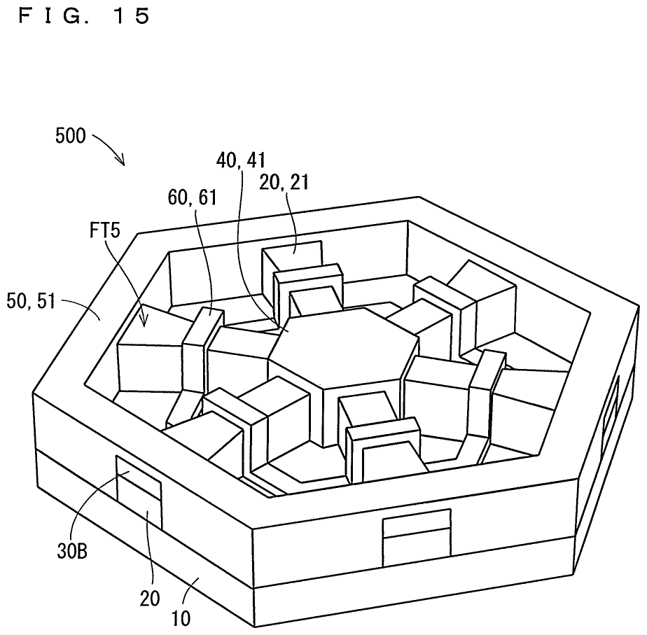

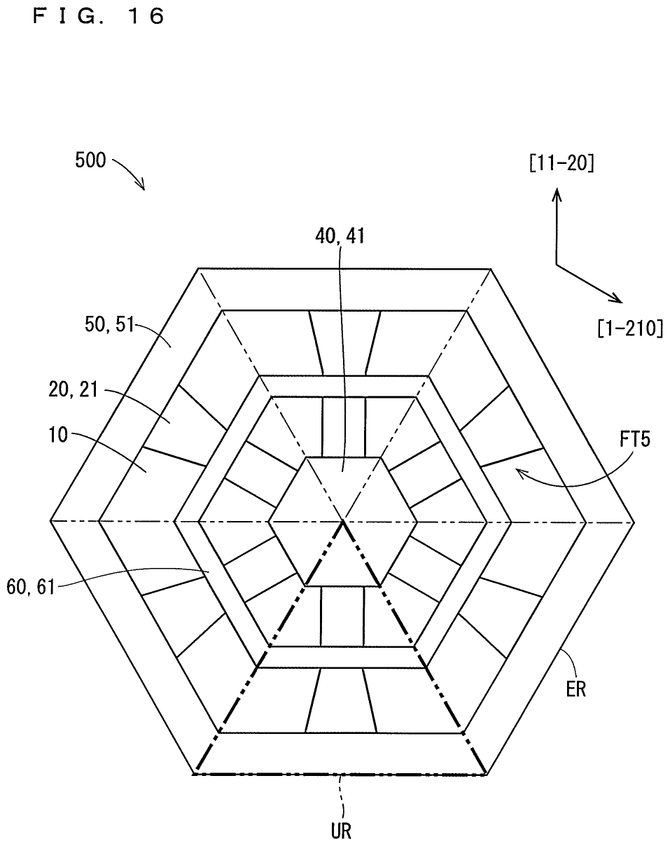

FIG. 15 is a perspective view illustrating a structure of a semiconductor device 500 according to Embodiment 5. FIG. 16 is a top view illustrating the structure of the semiconductor device 500.

In a fin transistor FT5 according to Embodiment 5, a width of a portion of the fin 21 over which the gate electrode 60 crosses is narrower than a width of a portion of the fin 21 in which the second contact region 30B is formed. The width of the fin 21 according to Embodiment 5 is continuously increased from the portion over which the gate electrode 60 crosses toward a portion immediately below the source electrode 50.

When an operating voltage, that is, an electric field intensity to be applied to a channel is high in a field effect transistor (FET), charges in a channel immediately below the gate electrode 60 are efficiently transported by an intense electric field. This consequently increases a rate of transporting charges immediately below the gate electrode 60 more than a rate of supplying charges from the source electrode 50 toward the channel. Thus, the output current of the transistor is saturated.

Since the width of the portion of the fin 21 over which the gate electrode 60 crosses is narrower than the width of the portion of the fin 21 in which the second contact region 30B is formed in Embodiment 5, supply of charges from the source electrode 50 toward the channel immediately below the gate electrode 60 is increased. This consequently suppresses saturation of the output current of the transistor. The output and the linearity of the semiconductor device 500 are improved more than those of the semiconductor device 100.

The width of the fin 21 may be increased stepwise from the portion over which the gate electrode 60 crosses toward the portion immediately below the source electrode 50.

The structure of the fin 21 according to Embodiment 5 may be applied to any one of the semiconductor devices 200 to 400. The semiconductor device produces the same advantages as described above.

### Embodiment 6

A semiconductor device and a method of manufacturing the same according to Embodiment 6 will be described. In Embodiment 6, the same references will be applied to the constituent elements identical to those in any one of Embodiments 1 to 5, and the detailed description thereof will be omitted.

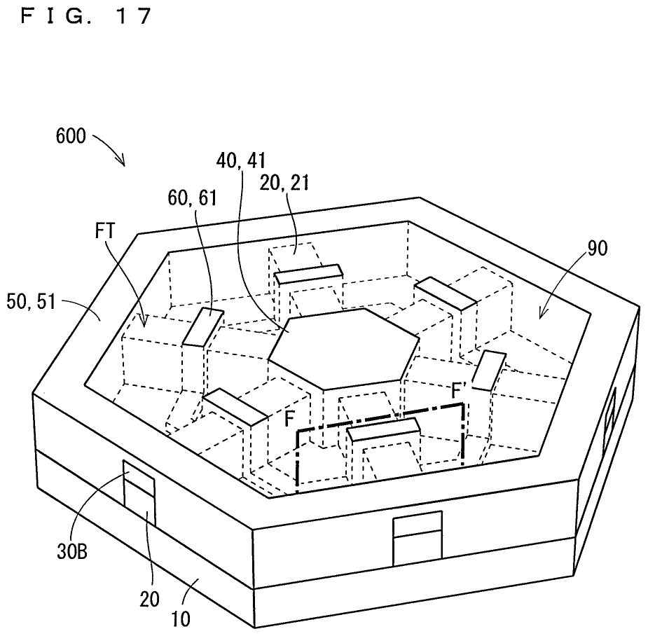

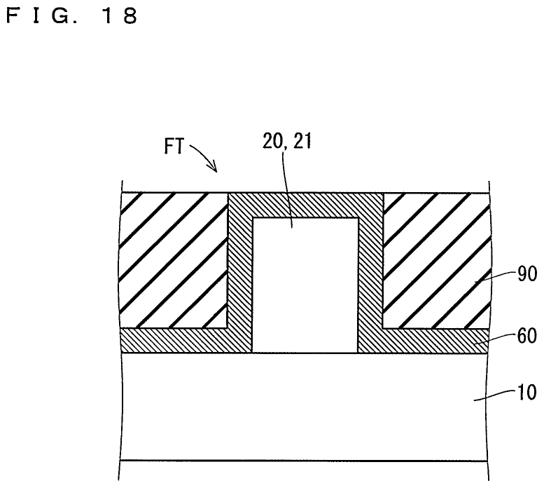

FIG. 17 is a perspective view illustrating a structure of a semiconductor device 600 according to Embodiment 6. FIG. 18 illustrates a structure of a fin transistor FT according to Embodiment 6. FIG. 18 is a cross-sectional view taken along F-F′ of FIG. 17. The structure of the fin transistor FT is identical to that according to Embodiment 1.

The semiconductor device 600 includes a filler 90. The filler 90 has insulating properties. The filler 90 fills the space between the adjacent two fin transistors FT. The filler 90 according to Embodiment 6 fills the space inside the ring-shaped source electrode 51 disposed at the outer periphery of the element region ER. The upper surfaces of the gate electrodes 60, the upper surfaces of the drain electrodes 40, and the upper surfaces of the source electrodes 50 are exposed from the filler 90.

The filler 90 is made of an oxide material, a nitride material, a mixed crystal material, a ceramic material, or diamond. The oxide may be a metal oxide or an oxide of a semiconductor. Examples of the oxide material include SiO₂, Al₂O₃, HfO₂, Gd₂O₃, Ta₂O₃, and ZrO₂. The nitride may be a metal nitride or a nitride of a semiconductor. Examples of the nitride material include SiN, AlN, TiN, and MoN. The mixed crystal material is a mixed crystal of the oxide material and the nitride material. The ceramic material is, for example, SiC.

The filler 90 preferably has a thermal conductivity higher than or equal to 0.1 W/mK. The filler 90 is preferably made of a material with a thermal conductivity higher than or equal to 200 W/mK, such as SiC or diamond.

The fins 21 generate heat when the fin transistors FT operate. The heat generated by the fins 21 is conducted to the filler 90 and spreads out. This reduces the temperature of the fins 21, and further reduces the channel temperature. The power efficiency and output power of the semiconductor device 600 are improved more than those of the semiconductor device 100.

The filler 90 may be applied to any one of the semiconductor devices 200 to 500. The semiconductor device produces the same advantages as described above.

Embodiments of the present disclosure can be freely combined, and appropriately modified or omitted.

### EXPLANATION OF REFERENCE SIGNS

10 substrate, 20 semiconductor layer, 20A lower layer, 20B upper layer, 21 fin, 30A first contact region, 30B second contact region, 40 drain electrode, 41 common drain electrode, 50 source electrode, 51 ring-shaped source electrode, 60 gate electrode, 61 ring-shaped gate electrode, 70 gate insulating film, 80 insulating film, 81 to 84 mask, 90 filler, 100 to 600 semiconductor device, ER to ER2 element region, FT to FT5 fin transistor, UR to UR2 unit element region.

1. A semiconductor device, comprising:
a substrate including a principal surface;
a semiconductor layer formed as a surface layer of the substrate or formed on the principal surface of the substrate, the semiconductor layer having a crystal structure in which an angle between two of a plurality of crystal orientations with equivalent relationships on a crystal plane having a correspondence with the principal surface of the substrate is 60 degrees, the surface layer being the principal surface of the substrate;
an element region including a plurality of unit element regions formed on the principal surface of the substrate; and
multiple fin transistors formed in the semiconductor layer, in the respective unit element regions,
wherein the multiple fin transistors radially extend from a center toward an outer periphery of the element region, and
adjacent two of the multiple fin transistors have a spacing with a 60° angle or a 120° angle.

2. The semiconductor device according to claim 1,
wherein each of the multiple fin transistors in the semiconductor layer extends in one of the plurality of crystal orientations.

3. The semiconductor device according to claim 1,
wherein the element region has a planar arrangement with 6-fold symmetry, and
the adjacent two of the multiple fin transistors have the spacing with the 60° angle.

4. The semiconductor device according to claim 1,
wherein the element region has a planar arrangement with 3-fold symmetry, and
the adjacent two of the multiple fin transistors have the spacing with the 120° angle.

5. The semiconductor device according to claim 1,
wherein the semiconductor layer has a first conductivity type,
each of the multiple fin transistors includes:
a fin formed in the semiconductor layer, having a protruding shape in a cross section, and extending from the center toward the outer periphery of the element region;
a first electrode in contact with a first contact region of a second conductivity type, the first contact region being formed in a surface layer and at a first end of the fin, the first end being located at the center of the element region;
a second electrode in contact with a second contact region of the second conductivity type, the second contact region being formed in the surface layer and at a second end of the fin, the second end being opposite to the first end; and
a gate electrode formed across the fin and between the first contact region and the second contact region, and
the element region includes a ring-shaped gate electrode obtained by connecting the gate electrode in one of the plurality of unit element regions to the gate electrodes in unit element regions adjacent to the one of the plurality of unit element regions.

6. The semiconductor device according to claim 5,
wherein the first electrode is a drain electrode, and
the second electrode is a source electrode.

7. The semiconductor device according to claim 5,
wherein the first electrode is a source electrode, and
the second electrode is a drain electrode.

8. The semiconductor device according to claim 5,
wherein the gate electrode is directly in contact with a part of both side surfaces of the fin, between the first contact region and the second contact region.

9. The semiconductor device according to claim 5,
wherein the gate electrode includes a semiconductor containing impurities, and
the fin includes:
a lower layer with a conductivity type identical to a conductivity type of the gate electrode; and
an upper layer with a conductivity type different from the conductivity type of the gate electrode.

10. The semiconductor device according to claim 5,
wherein each of the multiple fin transistors further includes a gate insulating film at least partially between the gate electrode and the fin.

11. The semiconductor device according to claim 5,
wherein each of the multiple fin transistors further includes an insulating film covering a region not covered with the gate electrode, on both side surfaces and an upper surface of the fin.

12. The semiconductor device according to claim 5,
wherein a width of a portion of the fin over which the gate electrode crosses is narrower than a width of a portion of the fin in which the second contact regions is formed.

13. The semiconductor device according to claim 5, further comprising
a filler having insulating properties and filling space between the adjacent two of the multiple fin transistors,
wherein upper surfaces of the gate electrodes, upper surface of the first electrodes, and upper surfaces of the second electrodes are exposed from the filler.

14. The semiconductor device according to claim 13,
wherein the filler has a thermal conductivity higher than or equal to 0.1 W/mK.

15. The semiconductor device according to claim 5,
wherein the element region includes:
a ring-shaped second electrode at the outer periphery of the element region, the ring-shaped second electrode being obtained by connecting the second electrode in one of the plurality of unit element regions to the second electrodes in unit element regions adjacent to the one of the plurality of unit element regions; and
a common first electrode at the center of the element region, the common first electrode being obtained by connecting the first electrode in one of the plurality of unit element regions to the first electrodes in unit element regions adjacent to the one of the plurality of unit element regions.

16. A method of manufacturing a semiconductor device, the method comprising the steps of:
preparing a substrate including a principal surface;
forming a semiconductor layer as a surface layer of the substrate or on the principal surface of the substrate, the semiconductor layer having a crystal structure in which an angle between two of a plurality of crystal orientations with equivalent relationships on a crystal plane having a correspondence with the principal surface of the substrate is 60 degrees, the surface layer being the principal surface of the substrate; and
forming, on the principal surface of the substrate, an element region including a plurality of unit element regions,
wherein the step of forming the element region includes a step of forming multiple fin transistors in the semiconductor layer, in the respective unit element regions,
the multiple fin transistors radially extend from a center toward an outer periphery of the element region, and
adjacent two of the multiple fin transistors have a spacing with a 60° angle or a 120° angle.

17. The semiconductor device according to claim 2,
wherein the element region has a planar arrangement with 6-fold symmetry, and
the adjacent two of the multiple fin transistors have the spacing with the 60° angle.

18. The semiconductor device according to claim 2,
wherein the element region has a planar arrangement with 3-fold symmetry, and
the adjacent two of the multiple fin transistors have the spacing with the 120° angle.

19. The semiconductor device according to claim 2,
wherein the semiconductor layer has a first conductivity type,
each of the multiple fin transistors includes:
a fin formed in the semiconductor layer, having a protruding shape in a cross section, and extending from the center toward the outer periphery of the element region;
a first electrode in contact with a first contact region of a second conductivity type, the first contact region being formed in a surface layer and at a first end of the fin, the first end being located at the center of the element region;
a second electrode in contact with a second contact region of the second conductivity type, the second contact region being formed in the surface layer and at a second end of the fin, the second end being opposite to the first end; and
a gate electrode formed across the fin and between the first contact region and the second contact region, and
the element region includes a ring-shaped gate electrode obtained by connecting the gate electrode in one of the plurality of unit element regions to the gate electrodes in unit element regions adjacent to the one of the plurality of unit element regions.

20. The semiconductor device according to claim 3,
wherein the semiconductor layer has a first conductivity type,
each of the multiple fin transistors includes:
a fin formed in the semiconductor layer, having a protruding shape in a cross section, and extending from the center toward the outer periphery of the element region;
a first electrode in contact with a first contact region of a second conductivity type, the first contact region being formed in a surface layer and at a first end of the fin, the first end being located at the center of the element region;
a second electrode in contact with a second contact region of the second conductivity type, the second contact region being formed in the surface layer and at a second end of the fin, the second end being opposite to the first end; and
a gate electrode formed across the fin and between the first contact region and the second contact region, and
the element region includes a ring-shaped gate electrode obtained by connecting the gate electrode in one of the plurality of unit element regions to the gate electrodes in unit element regions adjacent to the one of the plurality of unit element regions.
